(19) United States
(12) Patent Application Publication
(10) Pub. No.: US 2006/0043073 A1
(43) Pub. Date: Mar. 2, 2006

(54) Substrate treating method and apparatus

(75) Inventors: Hajime Shirakawa, Kyoto (JP); Atsushi Osawa, Kyoto (JP)

Correspondence Address: OSTROLENK FABER GERB & SOFFEN, 1180 AVENUE OF THE AMERICAS, NEW YORK, NY, 100368403, US

(73) Assignee: Dainippon Screen Mfg. Co., Ltd.

(21) Appl. No.: 11/208,811

(22) Filed: Aug. 22, 2005

(30) Foreign Application Priority Data
Aug. 24, 2004 (JP) JP2004-243821

(51) Int. Cl. C23F 1/00; H01L 21/306

(52) U.S. Cl. 216/90; 156/345.11

(57) ABSTRACT

A substrate treating method for performing deionized water treatment of substrates with a treating solution including deionized water. The method includes the steps of performing chemical treatment of the substrates with a treating solution including a chemical solution, and supplying deionized water and performing deionized water treatment. The step of performing deionized water treatment is executed by using a treating solution having a specific resistance value lower than a reference specific resistance value of deionized water. The deionized water treatment is terminated in a deionized water treating time that elapses before the reference specific resistance value is attained.

### BACKGROUND OF THE INVENTION

(1) Field of the Invention

This invention relates to a substrate treating method and apparatus for treating semiconductor wafers, glass substrates for photomasks, glass substrates for liquid crystal displays and substrates for optical disks (hereinafter simply called substrates), with a treating solution including deionized water after chemical treatment.

(2) Description of the Related Art

A conventional apparatus that executes this type of method includes a first treating tank for storing a chemical, a first deionized water treating tank for storing deionized water, a second treating tank for storing a chemical, a second deionized water treating tank for storing deionized water, and measuring instruments for measuring the specific resistance values in the first and second deionized water treating tanks, respectively.

With the apparatus having such a construction, substrates having undergone treatment with the chemical in the first or second treating tank are transferred to the first or second deionized water treating tank to be cleaned with deionized water. When a specific resistance value measured with the measuring instrument reaches a predetermined reference specific resistance value, it is determined that the cleaning treatment is complete. Then, the substrates are transferred to another treating tank for treatment with a next treating solution, or a series of treatments of the substrates is ended (see Japanese Unexamined Patent Publication No. 2001-210616, for example). The reference specific resistance value noted above is a value very close to the specific resistance value of deionized water.

Even with a substrate treating apparatus that treats substrates in a single treating tank while introducing a chemical and deionized water by turns, the chemical is replaced with deionized water, and the substrates are cleaned until a specific resistance value of a treating solution including the deionized water at that time reaches the reference specific resistance value. Then, the substrates are put to a next treatment.

The conventional apparatus noted above have the following drawbacks.

In the conventional method, the deionized water cleaning treatment is continued until the reference specific resistance value is reached. Thus, the cleaning treatment takes a long time, resulting in drawbacks of lowering throughput and consuming a large quantity of deionized water. The deionized water used in the cleaning treatment contains chemicals and the like, though in trace quantities, and cannot be drained as it is. The used deionized water can be drained only after purifying treatment. It is therefore an important question how to reduce the consumption of deionized water in cleaning treatment.

### SUMMARY OF THE INVENTION

This invention has been made having regard to the state of the art noted above, and its object is to provide a substrate treating method and apparatus which realize a time-saving deionized water cleaning treatment preceding a final deionized water cleaning treatment, thereby increasing throughput and reducing the consumption of deionized water.

A substrate treating method for performing deionized water treatment of substrates with a treating solution including deionized water, according to this invention, comprises the steps of performing chemical treatment of the substrates with a treating solution including a chemical solution; and supplying deionized water and performing deionized water treatment; wherein the step of performing deionized water treatment is executed by using a treating solution having a specific resistance value lower than a reference specific resistance value of deionized water, the deionized water treatment being terminated in a deionized water treating time that elapses before the reference specific resistance value is attained.

Deionized water is supplied after the chemical treatment to perform deionized water cleaning treatment. The deionized water cleaning treatment need not be performed until the specific resistance value of the treating solution including the deionized water reaches the reference specific resistance value of deionized water. That is, even if the specific resistance value of the treating solution recovers only to a value lower than the specific resistance value of deionized water, a shortened cleaning time is acceptable as long as excellent device performance can be maintained.

Thus, the treating solution including the deionized water first shows a specific resistance value lower than the reference specific resistance value of deionized water. Performance of the device on the substrates is evaluated after carrying out deionized water treatment with the treating solution for various periods of time shorter than deionized water treatment using deionized water of the reference specific resistance value. As a result, a cleaning time that can assure required device performance is determined and set as a shortened deionized water treating time. Deionized water treatment of the substrates may be carried out for that treating time. By finishing the deionized water treatment in the shortened deionized water treating time in this way, the treating time is shortened to increase throughput while maintaining excellent device performance, and the consumption of deionized water can also be reduced.

In this invention, the deionized water treatment may include at least two, preceding and final, deionized water treatments, the preceding deionized water treatment being performed by using the treating solution having a specific resistance value lower than the reference specific resistance value of deionized water, and terminated in the deionized water treating time that elapses before the reference specific resistance value is attained.

The final deionized water treatment noted above refers to a final one of deionized water treatments performed after chemical treatment.

In another aspect of the invention, a substrate treating method is provided for performing deionized water treatment of substrates with a treating solution including deionized water, comprising the steps of performing chemical treatment of the substrates with a chemical solution stored in a treating tank; and performing deionized water treatment with a treating solution while supplying deionized water to the treating tank to replace the chemical solution with the deionized water in the treating tank; wherein the step of performing deionized water treatment is executed such that the deionized water treatment is terminated in a deionized water treating time that elapses before a specific resistance value of the treating solution reaches a reference specific resistance value of deionized water as the chemical solution is replaced with the deionized water.

After the chemical treatment, deionized water cleaning treatment is performed with a treating solution while supplying deionized water to replace the chemical solution with the deionized water. The deionized water cleaning treatment need not be performed until the specific resistance value of the treating solution including the deionized water reaches the reference specific resistance value of deionized water. That is, even if the specific resistance value of the treating solution recovers only to a value lower than the specific resistance value of deionized water, a shortened deionized water cleaning time is acceptable as long as excellent device performance can be maintained.

Thus, the treating solution including the deionized water first shows a specific resistance value lower than the reference specific resistance value of deionized water. Performance of the device on the substrates is evaluated after carrying out deionized water treatment with the treating solution for various periods of time shorter than deionized water treatment using deionized water of the reference specific resistance value. As a result, a cleaning time that can assure required device performance is determined and set as a shortened deionized water treating time. Deionized water treatment of the substrates may be carried out for that treating time. By finishing the deionized water treatment in the shortened deionized water treating time in this way, the treating time is shortened to increase throughput while maintaining excellent device performance, and the consumption of deionized water can also be reduced.

The deionized water treating time may be set beforehand based on one of a particle adhesion state, a metal contamination state and etching uniformity occurring after the deionized water treatment.

By evaluating a particle adhesion state, a metal contamination state or etching uniformity occurring after the deionized water treatment, a shortened deionized water treating time that can assure required device performance may be determined.

In a further aspect of the invention, a substrate treating apparatus is provided for performing deionized water treatment of substrates with a treating solution including deionized water, comprising a treating tank for storing a chemical solution and the treating solution; a holding mechanism for holding the substrates in the treating tank; a deionized water supplying device for supplying deionized water to the treating tank where the substrates held by the holding mechanism are immersed in the chemical solution, thereby to replace the chemical solution with the deionized water in the treating tank; a storage device for storing a deionized water treating time that elapses before a specific resistance value of the treating solution reaches a reference specific resistance value of deionized water as the chemical solution is replaced with the deionized water; and a controller for causing the deionized water treatment to be performed for the deionized water treating time stored in the storage device.

After the chemical treatment, deionized water cleaning treatment is performed with a treating solution while supplying deionized water to replace the chemical solution with the deionized water in the treating tank. The deionized water cleaning treatment need not be performed until the specific resistance value of the treating solution including the deionized water reaches the reference specific resistance value of deionized water. That is, even if the specific resistance value of the treating solution recovers only to a value lower than the specific resistance value of deionized water, a shortened deionized water cleaning time is acceptable as long as excellent device performance can be maintained.

Thus, the treating solution including the deionized water first shows a specific resistance value lower than the reference specific resistance value of deionized water. Performance of the device on substrates is evaluated after carrying out deionized water treatment with the treating solution for various periods of time shorter than deionized water treatment using deionized water of the reference specific resistance value. As a result, a cleaning time that can assure required device performance is determined and stored in the storage device as a shortened deionized water treating time. The controller may cause the deionized water treatment to be performed for that time. By finishing the deionized water treatment in the shortened deionized water treating time in this way, the treating time is shortened to increase throughput while maintaining excellent device performance, and the consumption of deionized water can also be reduced.

### BRIEF DESCRIPTION OF THE DRAWINGS

For the purpose of illustrating the invention, there are shown in the drawings several forms which are presently preferred, it being understood, however, that the invention is not limited to the precise arrangement and instrumentalities shown.

FIG. 1 is a graph showing specific resistance values according to elapsed time after opening a measuring valve;

FIG. 2 is a graph showing uniformity over substrate surfaces according to deionized water treating time after etching treatment with hydrofluoric acid;

FIG. 3 is a table showing evaluations for varied periods of deionized water treating time;

FIG. 4 is a block diagram showing an outline of a substrate treating apparatus according to this invention;

FIG. 5 is a flow chart showing a procedure of treatment; and

FIG. 6 is an explanatory view showing operation of a substrate treating apparatus having a plurality of treating tanks.

### DESCRIPTION OF THE PREFERRED EMBODIMENTS

Preferred embodiments of this invention will be described in detail hereinafter with reference to the drawings.

<Substrate Treating Method>

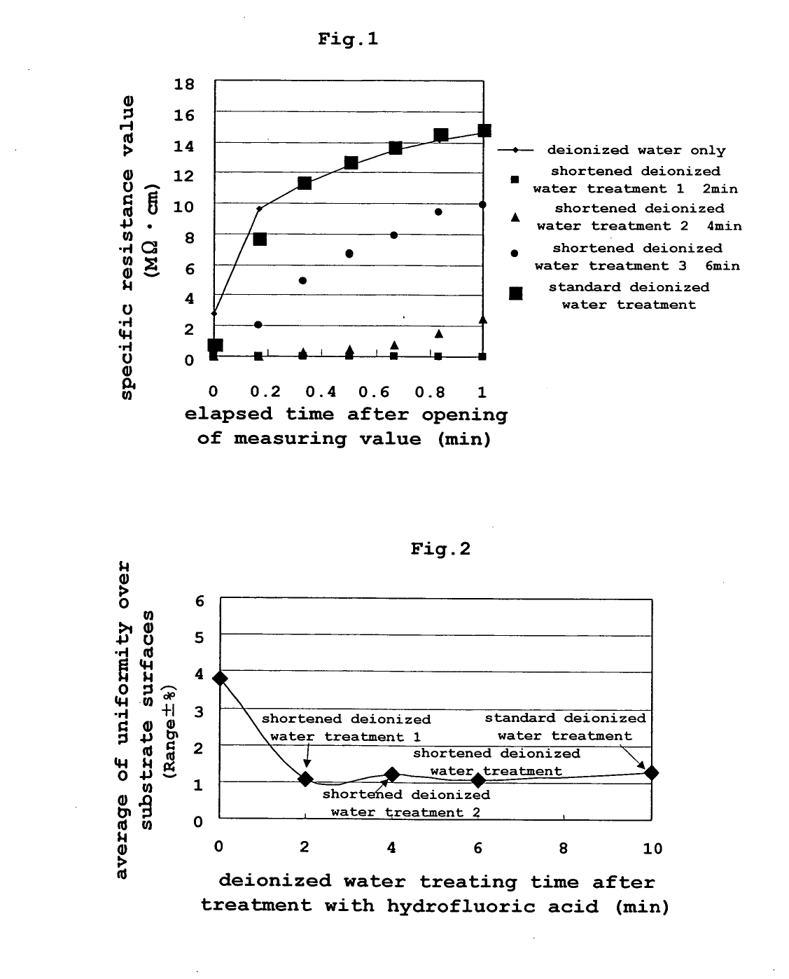

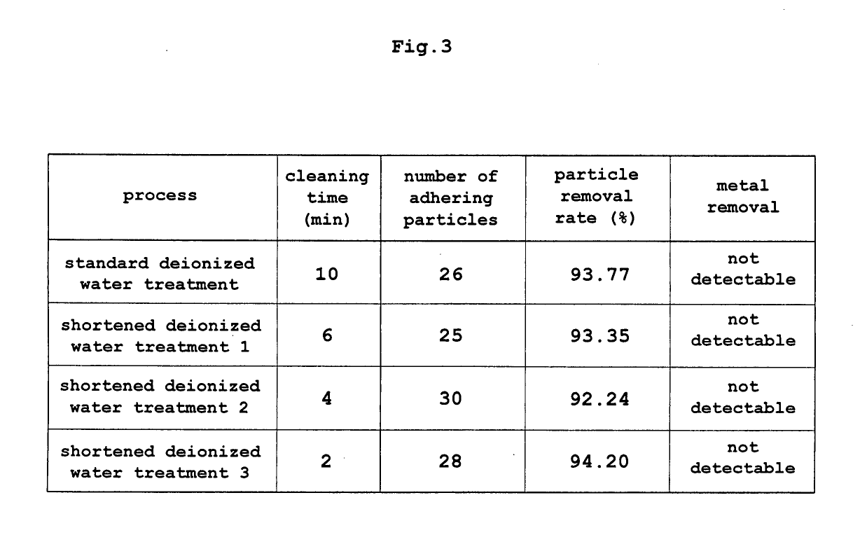

FIGS. 1 through 3 show examples of data for determining a shortened deionized water (pure water) treating time in this invention. FIG. 1 is a graph showing specific resistance values according to elapsed time after opening a measuring valve. FIG. 2 is a graph showing uniformity over substrate surfaces according to a deionized water treating time after etching treatment with hydrofluoric acid (chemical treatment). FIG. 3 is a table showing evaluations for varied deionized water treating times.

The graph of FIG. 1 shows variations of the specific resistance value occurring when the measuring valve is opened various periods of time from a point of time when deionized water begins to replace a chemical solution in a treating tank after substrates are treated with the chemical solution for a predetermined time. The specific resistance values are measured with a specific resistance meter attached to the treating tank. In the graph, the term “deionized water only” (shown in a solid line) represents variations occurring after a point of time when the measuring valve is opened after similar substrates are immersed in deionized water which begins to be replaced with a fresh supply of deionized water. The specific resistance value does not increase immediately because of a delay time in the measurement sample reaching the specific resistance meter after opening of the measuring valve, and characteristics of the specific resistance meter, for example.

Generally, “standard deionized water treating time” refers to a time required for cleaning treatment to be performed substantially until the specific resistance value of deionized water only is reached. Specifically, this is indicated as “standard deionized water treatment 10 min.” in FIG. 1. The specific resistance value at this time will be called herein “reference specific resistance value”. Examples of shortened deionized water treating time shorter than the standard deionized water treating time are indicated as “shortened deionized water treatment 1” for 2 minutes, “shortened deionized water treatment 2” for 4 minutes, and “shortened deionized water treatment 3” for 6 minutes. Thus, the time after starting replacement with deionized water until starting measurement becomes progressively shorter from “shortened deionized water treatment 3” to “shortened deionized water treatment 1”.

From this graph, examples of treatment showing variations in the specific resistance value less than the curves of “deionized water only” and “standard deionized water treating time” are considered inadequate treatment with deionized water according to the conventional criterion for determination. However, in this invention, characteristically, such determination is based on whether device performance can be maintained or not. Examples of criteria, as described hereinafter, include uniformity over substrate surfaces after etching and deionized water treatments (FIG. 2), particle adhesion and metal removal after deionized water treatment (FIG. 3).

“Uniformity over Substrate Surfaces after Etching”

FIG. 2 plots etching uniformity over substrate surfaces resulting from the above-noted various deionized water treatments carried out after the film on the substrate surfaces was etched to a thickness of 100 A with hydrofluoric acid of 200:1. In this graph, deionized water treating time “0” indicates that, after immersing and etching substrates in hydrofluoric acid, the hydrofluoric acid was simply drained off and no deionized water treatment took place. The 10 minutes, which are “standard deionized water treating time”, show etching uniformity over substrate surfaces obtained after conventional cleaning treatment. It will be seen that, as opposed to this, even shortened deionized water treatments 1-3 shorter than the standard deionized water treating time of 10 minutes result in etching uniformity similar to the uniformity obtained from the conventional treatment.

“Particle Adhesion and Metal Removal”

FIG. 3 shows numbers and removal rates of adhering particles and measurements of metal removal for the above-noted various deionized water treating times. The numbers of adhering particles show differences between numbers of adhering particles counted with a particle counter before and after the deionized water treatments. The particle removal rates show the rates according to the differences. The metal removal shows results of measurement of adhering metal.

It will be clear that the numbers and removal rates of adhering particles and the measurements of metal removal are at almost the same levels for the standard deionized water treatment and shortened deionized water treatments 1-3. The detection impossible level for the metal removal indicates that there occurs no contamination by metal so that the detection of metal is impossible with measuring devices.

Based on these results, this invention replaces a chemical solution with deionized water to use a treating solution (including the deionized water) having a specific resistance value lower than the reference specific resistance value of deionized water for the standard deionized water treatment. Substrates are cleaned for a shortened deionized water treating time shorter than the standard deionized water treating time, and yet capable of maintaining excellent device performance. However, for caution's sake, it is preferable to perform a final cleaning treatment until the reference specific resistance value is obtained as in the prior art. Deionized water cleaning treatment preceding the final cleaning treatment is performed for a “shortened deionized water treating time”.

An appropriate “shortened deionized water treating time” varies with the type of substrates, the type of film coated on the substrates, processes carried out on the substrates, the type and treating time of a chemical solution used, the construction of the treating tank, the mode of supplying deionized water, and so on. It is therefore desirable to carry out experiments beforehand for each of these factors, and determine a shortened deionized water treating time based on whether excellent device performance can be maintained or not.

<Substrate Treating Apparatus>

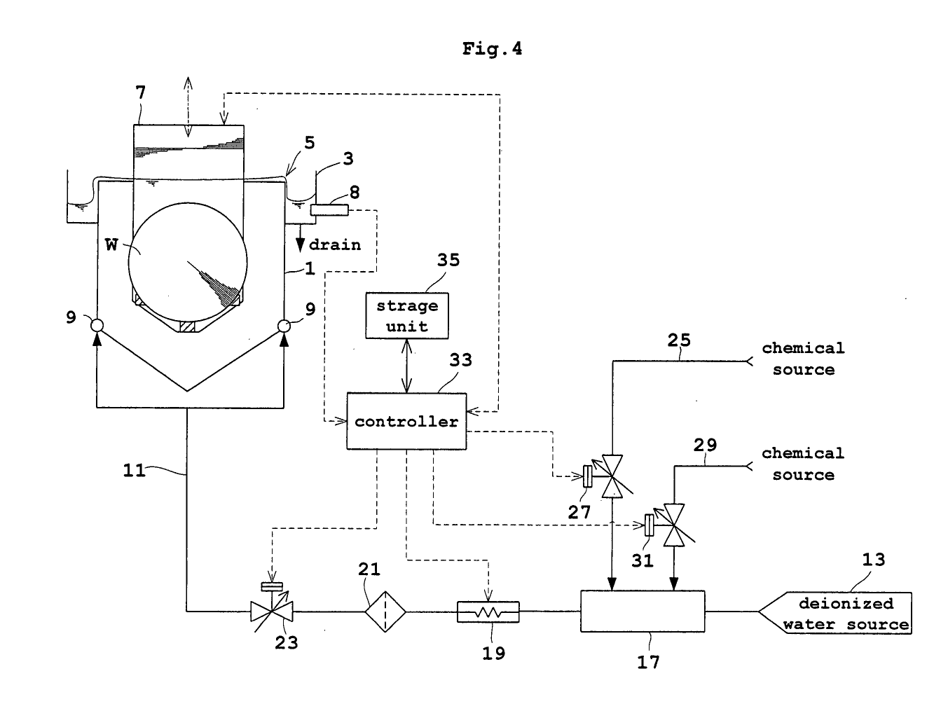

A substrate treating apparatus using the above substrate treating method will be described with reference to FIG. 4. FIG. 4 is a block diagram showing an outline of a substrate treating apparatus according to this invention.

The substrate treating apparatus includes an inner tank 1 and an outer tank 3 constituting a treating tank 5. The inner tank 1 stores treating liquids, e.g. deionized water serving as a rinsing liquid and a chemical solution, for treating substrates, or wafers W, immersed therein. The outer tank 3 has a function to collect and drain off the treating liquids overflowing the inner tank 1. A holding arm 7 corresponding to the holding mechanism in this invention is vertically movable between a position inside the inner tank 1 and a position thereabove. The holding arm 7 is constructed for holding a plurality of wafers W at edges thereof and maintaining the wafers W in upstanding posture. The outer tank 3 has a specific resistance meter 8 attached thereto for measuring specific resistance values of the treating liquids stored in the outer tank 3.

The specific resistance meter 8 corresponds to the measuring device in this invention.

The inner tank 1 includes filling pipes 9 arranged in the bottom thereof for supplying the treating liquids to the inner tank 1. The filling pipes 9 are connected to one end of supply piping 11. A deionized water source 13 is connected to the other end of supply piping 11. The supply piping 11 has, arranged thereon downstream of the deionized water source 13, a mixing valve 17, an in-line heater 19, a filter 21 and a control valve 23.

The mixing valve 17 has, connected thereto, supply piping 25 communicating with a chemical source. A control valve 27 is mounted on the supply piping 25 for adjusting a flow rate therethrough. Another supply piping 29 is connected to the mixing valve 17, which piping 29 is in communication with a chemical source for supplying a different chemical. A flow rate through the supply piping 29 is adjusted by a control valve 31.

A controller 33 exercises an overall control of the apparatus including the vertical movement of the holding arm 7 described above, temperature control through the in-line heater 19, and flow adjustments through the control valves 23, 27 and 31. The controller 33 has a storage unit 35 connected thereto, which stores a recipe and the like specifying procedures for treating wafers W. The controller 33, while referring to the recipe, controls each component noted above. When a final deionized water cleaning treatment is in progress, the controller 33 determines a completion of the treatment while referring to specific resistance values. In the case of deionized water cleaning treatment carried out before the final deionized water cleaning treatment, the controller 33 terminates this treatment according to a “shortened deionized water treating time” specified in the recipe, and moves on to a next treatment.

The above controller 33 corresponds to the controller in this invention, and the storage unit 35 corresponds to the storage device in this invention.

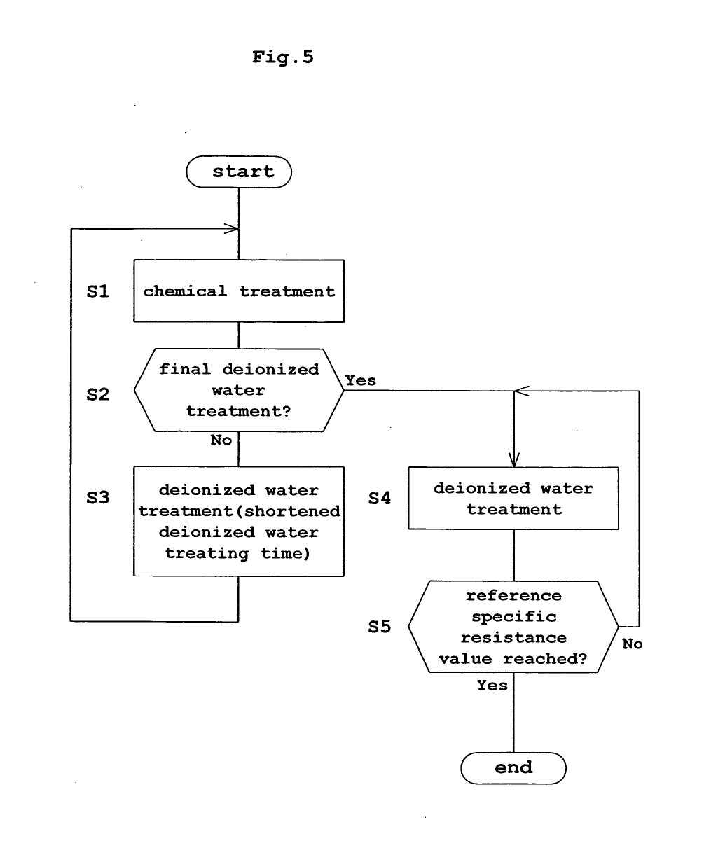

Next, treatment by the substrate treating apparatus having the above construction will be described with reference to FIG. 5. FIG. 5 is a flow chart showing a procedure of treatment.

Step S1

The controller 33 refers to the recipe in the storage unit 35, and supplies a predetermined chemical solution to the inner tank 1 by controlling the control valves 23, 27 and/or 31 and, as necessary, the in-line heater 17. The chemical solution supplied is, for example, hydrofluoric acid for etching. Next, the holding arm 7 supporting wafers W is lowered into the inner tank 1, and maintained therein for a time specified in the recipe. By this chemical treatment, for example, oxide film formed on the wafers W is etched to a predetermined thickness.

Step S2

The controller 33 refers to the recipe and supplies deionized water having the reference specific resistance value to the inner tank 1, for performing deionized water treatment of the wafers W with a treating solution including the deionized water. Subsequent treatment depends on whether this is the final deionized water treatment or not.

Step S3

When it is determined in the above step S2 that this is not the final deionized water treatment, upon lapse of a predetermined time of chemical treatment, the controller 33, while maintaining the holding arm 7 in the position for treatment, closes the control valves 27 and 31, and adjusts the control valve 23 to supply deionized water at a predetermined flow rate from the deionized water source 13 to the inner tank 1. As a result, the chemical solution in the inner tank 1 is replaced by the deionized water, to perform deionized water treatment of the wafers W with the treating solution including the deionized water. Its treating time is the shortened deionized water treating time noted above. This shortened deionized water treating time (one of shortened deionized water treatments 1-3) is stored in the storage unit 35, and the deionized water treatment of the wafers W is carried out under control of the controller 33.

After this treatment, the operation returns to step S1 for performing chemical treatment using a different chemical, for example.

Step S4

When it is determined in the above step S2 that the final deionized water treatment is in progress, the standard deionized water treating time is adopted instead of the shortened deionized water treating time.

Step S5

In the case of the final deionized water treatment, the controller 33 monitors specific resistance values outputted from the specific resistance meter 8, and determines completion of the treatment when the value of the treating solution including deionized water reaches the reference specific resistance value specified in the recipe. Thus, step S4 is executed until the reference specific resistance value is reached. The final deionized water treatment is ended when the reference specific resistance value is reached.

As described above, the deionized water treatment preceding the final deionized water treatment (for example, 10 minutes) finishes in the shortened deionized water treating time (e.g. 2 minutes, 4 minutes or 6 minutes). Consequently, while maintaining excellent device performance, the treating time is shortened to increase throughput. Further, since the deionized water treatment is completed in a short time, the consumption of deionized water can also be reduced to lighten the load of wastewater treatment.

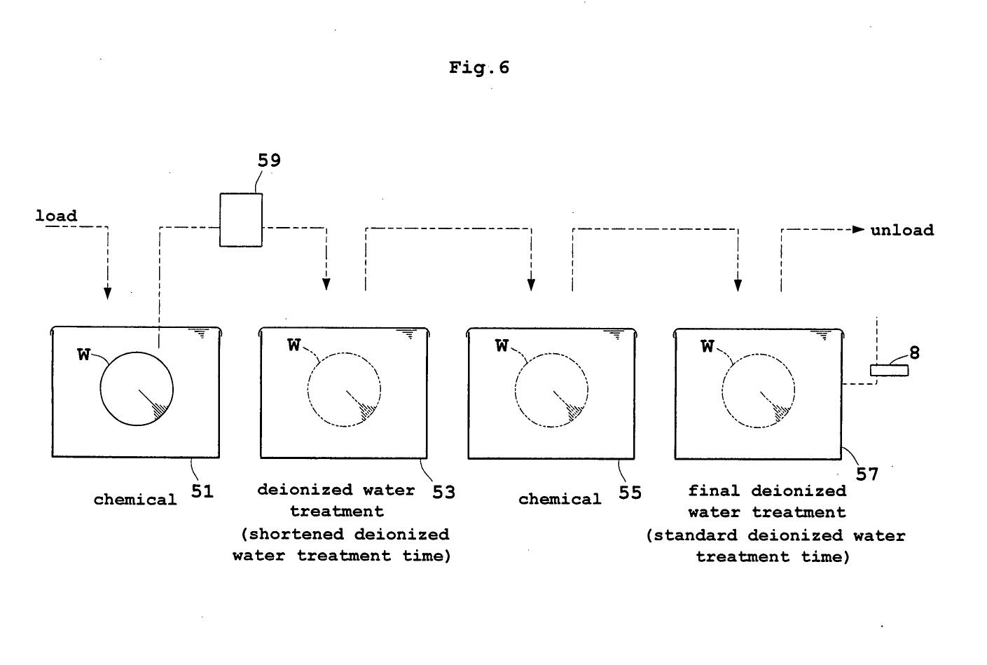

The above substrate treating apparatus is the type that performs chemical treatment and deionized water treatment in one treating tank 5, This invention is applicable also to an apparatus having a plurality of treating tanks. Such a case will be described with reference to FIG. 6. FIG. 6 is an explanatory view showing operation of a substrate treating apparatus having a plurality of treating tanks.

This substrate treating apparatus includes a treating tank 51 for first chemical treatment, a treating tank 53 for deionized water treatment, a treating tank 55 for second chemical treatment, and a treating tank 57 for final deionized water treatment. With this substrate treating apparatus, a transport mechanism 59 transports wafers W successively to the treating tanks 51, 53, 55 and 57 for treatment. FIG. 6 shows only inner tanks, with outer tanks omitted therefrom.

With the apparatus having the above construction, the wafers W are transported successively to the treating tanks 51, 53, 55 and 57 according to a recipe. The deionized water cleaning treatment preceding the final deionized water cleaning treatment is carried out for a “shortened deionized water treating time”, The final deionized water treatment is carried out while monitoring a specific resistance meter 8, to be finished when the reference specific resistance value is reached, or is carried out for a standard time.

The wafers W having undergone the final deionized water treatment are withdrawn from the treating tank 57 by the transport mechanism 59, put to a drying process, and are then stored away, or passed to a next series of processes.

Also with a construction of having a plurality of treating tanks as described above, the deionized water treatment preceding the final deionized water treatment is carried out for a “shortened deionized water treating time”.

Thus, while maintaining excellent device performance, the treating time is shortened to increase throughput. Further, since the deionized water treatment is completed in a short time, the consumption of deionized water can also be reduced.

This invention is not limited to the above embodiments, but may be modified as follows.

This invention is applicable to an apparatus having two treating tanks, e.g. a treating tank for deionized water treatment and a treating tank for chemical treatment. The deionized water treatment and chemical treatment are carried out at least once each by transporting substrates between these treating tanks.

This invention may be embodied in other specific forms without departing from the spirit or essential attributes thereof and, accordingly, reference should be made to the appended claims, rather than to the foregoing specification, as indicating the scope of the invention.

What is claimed is:

1. A substrate treating method for performing deionized water treatment of substrates with a treating solution including deionized water, comprising the steps of:
performing chemical treatment of the substrates with a treating solution including a chemical solution; and
supplying deionized water and performing deionized water treatment;
wherein the step of performing deionized water treatment is executed by using a treating solution having a specific resistance value lower than a reference specific resistance value of deionized water, the deionized water treatment being terminated in a deionized water treating time that elapses before said reference specific resistance value is attained.

2. A method as defined in claim 1, wherein said deionized water treatment includes at least two, preceding and final, deionized water treatments, said preceding deionized water treatment being performed by using the treating solution having a specific resistance value lower than the reference specific resistance value of deionized water, and terminated in the deionized water treating time that elapses before said reference specific resistance value is attained.

3. A substrate treating method for performing deionized water treatment of substrates with a treating solution including deionized water, comprising the steps of:
performing chemical treatment of the substrates with a chemical solution stored in a treating tank; and
performing deionized water treatment with a treating solution while supplying deionized water to the treating tank to replace the chemical solution with the deionized water in the treating tank;
wherein the step of performing deionized water treatment is executed such that the deionized water treatment is terminated in a deionized water treating time that elapses before a specific resistance value of the treating solution reaches a reference specific resistance value of the deionized water as the chemical solution is replaced with the deionized water.

4. A method as defined in claim 3, wherein said deionized water treatment includes at least two, preceding and final, deionized water treatments, said preceding deionized water treatment being performed while replacing the chemical solution with the deionized water, and terminated in the deionized water treating time that elapses before the specific resistance value of the treating solution reaches the reference specific resistance value of the deionized water as the chemical solution is replaced with the deionized water.

5. A method as defined in claim 1, wherein said deionized water treating time is set beforehand based on one of a particle adhesion state, a metal contamination state and etching uniformity occurring after the deionized water treatment.

6. A method as defined in claim 2, wherein said deionized water treating time is set beforehand based on one of a particle adhesion state, a metal contamination state and etching uniformity occurring after the deionized water treatment.

7. A method as defined in claim 3, wherein said deionized water treating time is set beforehand based on one of a particle adhesion state, a metal contamination state and etching uniformity occurring after the deionized water treatment.

8. A method as defined in claim 4, wherein said deionized water treating time is set beforehand based on one of a particle adhesion state, a metal contamination state and etching uniformity occurring after the deionized water treatment.

9. A substrate treating apparatus for performing deionized water treatment of substrates with a treating solution including deionized water, comprising:
a treating tank for storing a chemical solution and the treating solution;
a holding mechanism for holding the substrates in said treating tank;
a deionized water supplying device for supplying deionized water to said treating tank where the substrates held by said holding mechanism are immersed in the chemical solution, thereby to replace the chemical solution with the deionized water in said treating tank;
a storage device for storing a deionized water treating time that elapses before a specific resistance value of the treating solution reaches a reference specific resistance value of deionized water as the chemical solution is replaced with the deionized water; and
a controller for causing the deionized water treatment to be performed for the deionized water treating time stored in said storage device.

10. An apparatus as defined in claim 9, further comprising a measuring device for measuring the specific resistance value of the treating solution stored in said treating tank.

11. A substrate treating apparatus for performing deionized water treatment of substrates with a treating solution including deionized water, comprising:
a first treating tank for performing deionized water treatment of the substrates with the treating solution;
a second treating tank for performing chemical treatment with a chemical solution of the substrates having undergone the deionized water treatment in said first treating tank;
a third treating tank for performing deionized water treatment with the treating solution of the substrates having undergone the chemical treatment in said second treating tank;
a transport mechanism for transporting the substrates from said first treating tank to said second treating tank, and from said second treating tank to said third treating tank;
a storage device for storing a deionized water treating time that elapses before a specific resistance value of the treating solution reaches a reference specific resistance value of deionized water as the chemical solution is replaced with the deionized water in said first treating tank; and
a controller for causing the deionized water treatment to be performed in said first treating tank for the deionized water treating time stored in said storage device.

12. An apparatus as defined in claim 11, wherein said controller is arranged to cause said transport mechanism to withdraw the substrates from said third treating tank based on the specific resistance value of the treating solution having reached the reference specific resistance value of deionized water in said third treating tank.

13. An apparatus as defined in claim 9, wherein said deionized water treating time is set beforehand based on one of a particle adhesion state, a metal contamination state and etching uniformity occurring after the deionized water treatment.

14. An apparatus as defined in claim 10, wherein said deionized water treating time is set beforehand based on one of a particle adhesion state, a metal contamination state and etching uniformity occurring after the deionized water treatment.

15. An apparatus as defined in claim 11, wherein said deionized water treating time is set beforehand based on one of a particle adhesion state, a metal contamination state and etching uniformity occurring after the deionized water treatment.

16. An apparatus as defined in claim 11, wherein said deionized water treating time is set beforehand based on one of a particle adhesion state, a metal contamination state and etching uniformity occurring after the deionized water treatment.

17. An apparatus as defined in claim 9, wherein said chemical solution is hydrofluoric acid.

18. An apparatus as defined in claim 10, wherein said chemical solution is hydrofluoric acid.

19. An apparatus as defined in claim 11, wherein said chemical solution is hydrofluoric acid.

20. An apparatus as defined in claim 12, wherein said chemical solution is hydrofluoric acid.
